(19) United States
(12) Patent Application Publication
(10) Pub. No.: US 2016/0087239 A1
(43) Pub. Date: Mar. 24, 2016

(54) ORGANIC LIGHT EMITTING DIODE LIGHTING DEVICE

(71) Applicant: Ultimate Image Corporation, Miaoli County (TW)

(72) Inventor: CHIH-FENG SUNG, Miaoli County (TW)

(21) Appl. No.: 14/493,578

(22) Filed: Sep. 23, 2014

(51) Int. Cl. H01L 51/52

(52) U.S. Cl. CPC H01L 51/5246; H01L 2251/53

(57) ABSTRACT

An organic light emitting diode lighting device includes a substrate, an organic light emitting structure and at least two electrode terminal units. The substrate has a plurality of sides. The organic light emitting structure is disposed on the substrate, and a portion of the substrate is exposed from the organic light emitting structure. The organic light emitting structure has a first electrode layer, an organic light emitting layer and a second electrode layer sequentially laminated on the substrate. The electrode terminal units are disposed on the portion of the substrate exposed from the organic light emitting structure, and are located between one of the sides and the organic light emitting structure. The electrode terminal units are electrically connected with the first electrode layer and the second electrode layer, respectively.

### FIELD OF THE INVENTION

The present invention relates to a lighting device, and more particularly to an organic light emitting diode (OLED) lighting device.

### BACKGROUND OF THE INVENTION

Since an organic light emitting diode (OLED) has advantages such as self-luminous, low power consumption and fast response time, it has attracted extensive attention for the display and lighting applications. In an OLED, light rays are generated by electrically exciting fluorescent or phosphorescent organic compounds in the light emitting layer.

FIG. 1 is a cross-section diagram showing a conventional OLED lighting device 1. FIG. 2 is a schematic top view showing the conventional OLED lighting device 1 shown in FIG. 1. As shown in FIG. 1, the conventional OLED lighting device 1 includes a substrate 10, and an anode electrode layer 11, an organic light emitting layer 12 and a cathode electrode layer 13 sequentially laminated on the substrate 10. Moreover, an encapsulating cover 14 is fixed over the substrate 10 by a sealant 15. The anode electrode layer 11 and the cathode electrode layer 13 have connecting portions 110, 130, respectively. The connecting portions 110, 130 extend out of the encapsulating cover 14 for electrically connecting with an external power source (not shown).

As shown in FIG. 2, the connecting portions 110, 130 are distributed on the periphery of the substrate 10. In manufacturing the conventional OLED lighting device 1, in order to reserve space for disposing the connecting portions 110, 130 on the substrate 10, the organic light emitting layer 12 must be disposed at the center of the substrate 10, such that the periphery of the substrate 10 has sufficient and symmetric space for disposing the connecting portions 110, 130.

However, the OLED lighting device 1 with such a structure has a relatively smaller region for emitting light. Take an OLED lighting device with a size of 100 mm*100 mm as an example, the region for emitting light is only 87 mm*87 mm. In other words, the utilization of the overall light-emitting region is only 75.7%. Therefore, it is an issue for a person in the related art to effectively improve the utilization of the light-emitting region of the OLED lighting device.

### SUMMARY OF THE INVENTION

One object of the invention is to provide an organic light emitting diode (OLED) lighting device in which the utilization of the light-emitting region is effectively improved.

In order to achieve the above advantages, the invention provides an OLED lighting device including a substrate, an organic light emitting structure and at least two electrode terminal units. The substrate has a plurality of sides. The organic light emitting structure is disposed on the substrate, and a portion of the substrate is exposed from the organic light emitting structure. The organic light emitting structure has a first electrode layer, an organic light emitting layer and a second electrode layer sequentially laminated on the substrate. The electrode terminal units are disposed on the portion of the substrate exposed from the organic light emitting structure, and located between one of the sides and the organic light emitting structure. The electrode terminal units are electrically connected with the first electrode layer and the second electrode layer, respectively.

In an embodiment of the invention, the substrate is in a rectangle shape and the sides includes two opposite long sides and two opposite short sides, and the electrode terminal units are disposed between one of the short sides and the organic light emitting structure.

In an embodiment of the invention, a ratio of the length of each long side to the length of each short side is between 1.5 to 3.5.

In an embodiment of the invention, the OLED lighting device further includes a first baseline and a second baseline, wherein the first baseline passes through a centric position of the substrate, the second baseline passes through a centric position of the organic light emitting structure, and the first baseline and the second baseline do not overlap.

In an embodiment of the invention, the OLED lighting device further includes a protection layer disposed over the organic light emitting structure.

In an embodiment of the invention, the OLED lighting device further includes a sealant disposed between the protection layer and the substrate, wherein the protection layer is fixed over the substrate by the sealant.

In an embodiment of the invention, the protection layer is made of glass or plastic, and the sealant is made of an ultraviolet ray curable resin or a glass cement.

In an embodiment of the invention, the substrate further includes a wiring, and the first electrode layer and the second electrode layer are electrically connected with the electrode terminal units by the wiring, respectively.

In an embodiment of the invention, the first electrode layer is an anode electrode layer, and the second electrode layer is a cathode electrode layer.

In the OLED lighting device according to the invention, only the region between at least a side of the substrate and the organic light emitting structure is used to dispose the electrode terminal units, and the at least a side of the substrate is a short side of a rectangle, and the electrode terminal units are electrically connected with the first electrode layer and the second electrode layer by a wiring of the substrate. In such a structure design, the area of the substrate for disposing the organic light emitting structure can be greatly increased when comparing to a conventional structure, and thus the problem of low utilization of the light-emitting region can be effectively ameliorated.

### BRIEF DESCRIPTION OF THE DRAWINGS

The present invention will become more readily apparent to those ordinarily skilled in the art after reviewing the following detailed description and accompanying drawings, in which:

FIG. 1 is a cross-section diagram showing a conventional OLED lighting device;

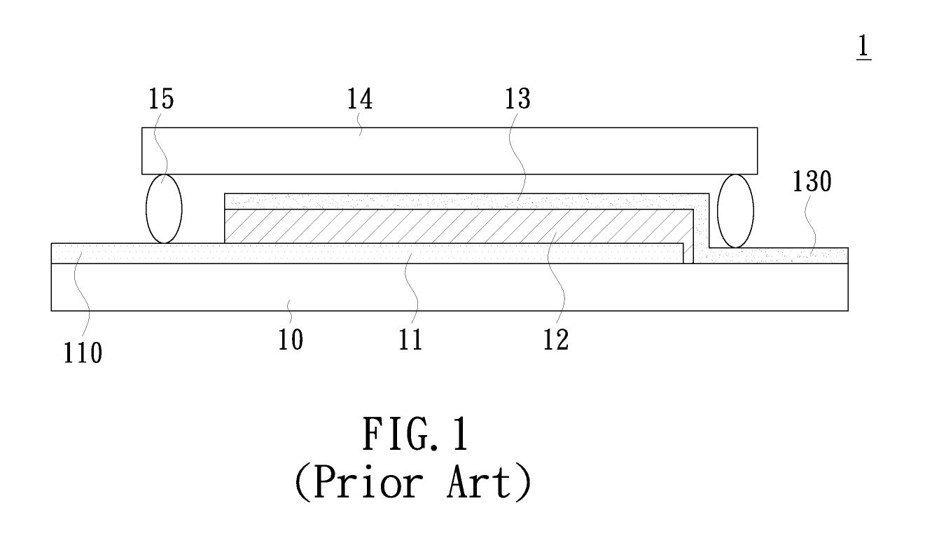

FIG. 2 is a schematic top view showing the conventional OLED lighting device shown in FIG. 1;

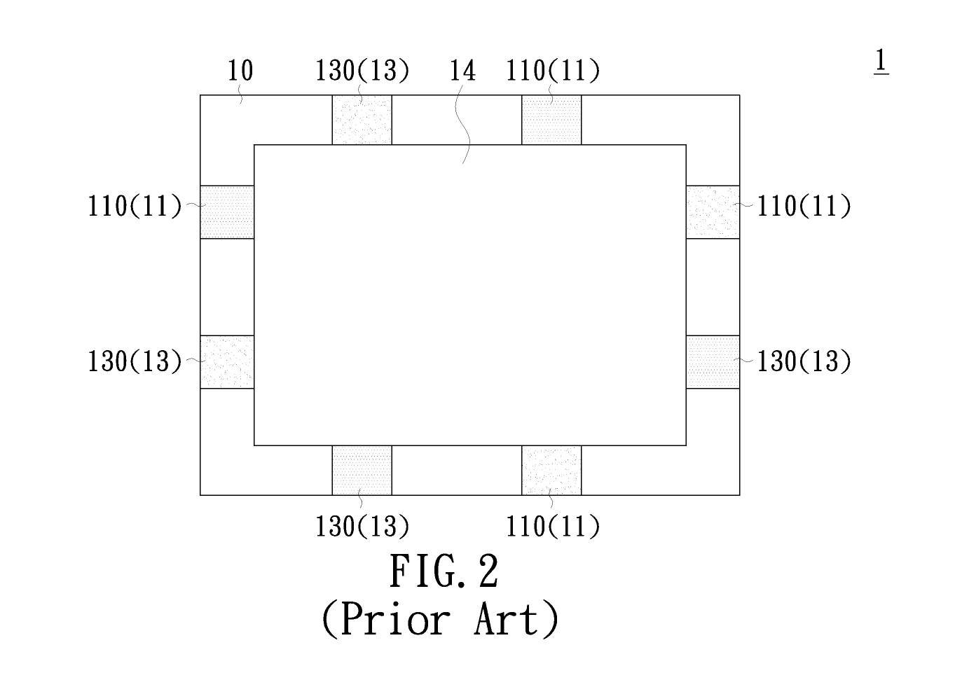

FIG. 3 is a cross-section diagram showing an OLED lighting device according to an embodiment of the invention; and

FIG. 4 is a schematic top view showing the OLED lighting device shown in FIG. 3.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

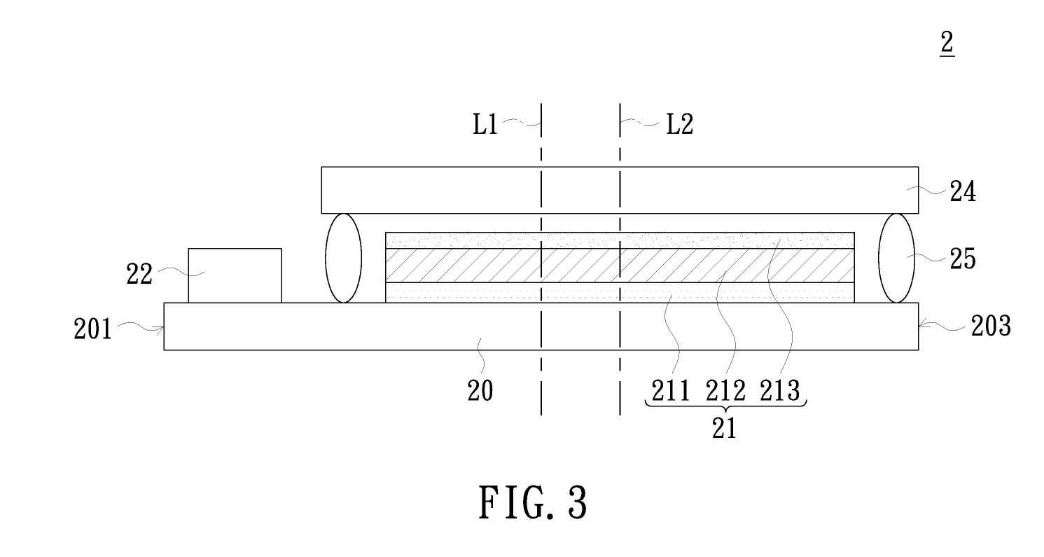

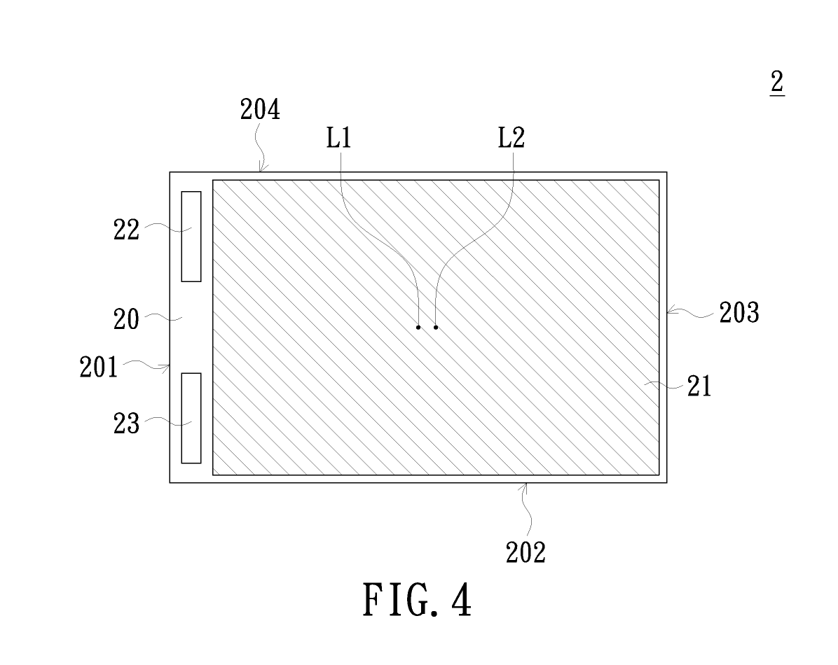

Referring to FIGS. 3 and 4, FIG. 3 is a cross-section diagram showing an organic light emitting diode (OLED) lighting device 2 according to an embodiment of the invention, and FIG. 4 is a schematic top view showing the OLED lighting device 2 shown in FIG. 3. As shown in FIGS. 3 and 4, the OLED lighting device 2 according to this embodiment includes a substrate 20, an organic light emitting structure 21 and at least two electrode terminal units 22, 23. The substrate 20 has a plurality of sides 201, 202, 203, 204 that are adjacent to each other. The organic light emitting structure 21 is disposed on the substrate 20, and a portion of the substrate 20 is exposed from the organic light emitting structure 21. The organic light emitting structure 21 has a first electrode layer 211, an organic light emitting layer 212 and a second electrode layer 213 sequentially laminated on the substrate 20. The electrode terminal unit 22, 23 are disposed on the portion of the substrate 20 exposed from the organic light emitting structure 21, and are located between one side 201 of the sides 201, 202, 203, 204 and the organic light emitting structure 21. The electrode terminal units 22, 23 are electrically connected with the first electrode layer 211 and the second electrode layer 213, respectively. The electrode terminal units 22, 23 are electrically connected with an external power source (not shown).

As shown in FIG. 3, the OLED lighting device 2 according to this embodiment further includes a protection layer 24 disposed over the organic light emitting structure 21 and a sealant 25 disposed between the protection layer 24 and the substrate 20. The protection layer 24 is fixed over the substrate 20 by the sealant 25. In this embodiment, the protection layer 24 is made of, but not limited to, glass or plastic. The sealant 25 is made of, but not limited to, an ultraviolet ray curable resin (UV resin) or a glass cement. Moreover, the substrate 20 according to this embodiment further includes a wiring (not shown), the first electrode layer 211 and the second electrode layer 213 are electrically connected with the electrode terminal units 22, 23 by the wiring, respectively. In this embodiment, the first electrode layer 211 can be, but not limited to, an anode electrode layer, and the second electrode layer 213 can be, but not limited to, a cathode electrode layer.

As shown in FIG. 4, the substrate 20 according to this embodiment is, for example, in a rectangle shape. The sides 201, 203 of the substrate 20 are two opposite short sides of the rectangle, and the sides 202, 204 of the substrate 20 are two opposite long sides of the rectangle. In this embodiment, the electrode terminal units 22, 23 are disposed between a short side (that is, the side 201) and the organic light emitting structure 21. Since the electrode terminal units 22, 23 are disposed only at the region nearby the side 201 of the substrate 20, there is no need to provide the regions of the substrate 20 nearby other three sides 202, 203, 204 for disposing the electrode terminal units. That is, the regions of the substrate 20 nearby other three sides 202, 203, 204 can be used for disposing the organic light emitting structure 21. In other words, an organic light emitting structure with a larger light-emitting area can be provided. In addition, since the electrode terminal units 22, 23 are disposed at the region nearby the short side (the side 201), the area for disposing the electrode terminal units 22, 23 is smaller when comparing with a region nearby a long side (the side 202 or 204). Therefore, such a structure design can effectively increase the utilization of the light-emitting region. For example, for a substrate 20 with a long side length of 103 mm and a short side length of 57 mm, the ratio of the long side to the short side is about 1.8, and an area of the substrate 20 for disposing the organic light emitting structure 21 can be up to 90%. It should be noted that, in order to clearly show the region where the organic light emitting structure 21 is disposed on the substrate 20, members such as the protection layer 24 and the sealant 25 are omitted in FIG. 4.

It is worth to mention that the ratio of the long side to the short side of the substrate 20 being about 1.8 is only an embodiment of the invention, and the invention is not limited to the value. In other embodiment, the ratio of the long side to the short side of the substrate 20 can be between 1.5 to 3.5. Moreover, the shape of the substrate 20 is not limited to a rectangle having long sides and short sides. In other embodiment, the shape of the substrate 20 can also be a square with four equal sides.

It should be noted that, in this embodiment, the shape of the organic light emitting structure 21 is substantially the same as the shape of the substrate 20, and the organic light emitting structure 21 is disposed on a position of the substrate 20 nearby the side 203. In details, as shown in FIGS. 3 and 4, the OLED lighting device 1 has a first baseline L1 and a second baseline L2. The first baseline L1 passes through a centric position of the substrate 20, and the second baseline L2 passes through a centric position of the organic light emitting structure 21, wherein the first baseline L1 and the second baseline L2 do not overlap with each other. In such a structure design, an interval between the side 201 (the short side) of the substrate 20 and the organic light emitting structure 21 can be increased. In other words, a region of the substrate 20 being exposed from the organic light emitting structure 21 is increased, so as to provide sufficient space for disposing the electrode terminal units 22, 23.

In summary, the structure of the OLED lighting device according to the invention has advantages as follows. That is, only the region between at least a side of the substrate and the organic light emitting structure is used to dispose the electrode terminal units, the at least a side of the substrate is a short side of a rectangle, and the electrode terminal units are electrically connected with the first electrode layer and the second electrode layer by a wiring of the substrate. In such a structure design, the area of the substrate for disposing the organic light emitting structure can be greatly increased when comparing to a conventional structure, and thus the problem of low utilization of the light-emitting region can be effectively ameliorated.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. An organic light emitting diode (OLED) lighting device, comprising:
a substrate having a plurality of sides;
an organic light emitting structure disposed on the substrate, and a portion of the substrate being exposed from the organic light emitting structure, the organic light emitting structure having a first electrode layer, an organic light emitting layer and a second electrode layer sequentially laminated on the substrate; and
at least two electrode terminal units disposed on the portion of the substrate exposed from the organic light emitting structure, and located between one of the sides and the organic light emitting structure, and the electrode terminal units being electrically connected with the first electrode layer and the second electrode layer, respectively, wherein the substrate is in a rectangle shape and the sides includes two opposite long sides and two opposite short sides, and the electrode terminal units are disposed between only one of the short sides and the organic light emitting structure.

2. (canceled)

3. The OLED lighting device according to claim 1, wherein a ratio of the length of each long side to the length of each short side is between 1.5 to 3.5.

4. The OLED lighting device according to claim 1, further comprising a first baseline and a second baseline, wherein the first baseline passes through a centric position of the substrate, the second baseline passes through a centric position of the organic light emitting structure, and the first baseline and the second baseline do not overlap.

5. The OLED lighting device according to claim 1, further comprising a protection layer disposed over the organic light emitting structure.

6. The OLED lighting device according to claim 5, further comprising a sealant disposed between the protection layer and the substrate, wherein the protection layer is fixed over the substrate by the sealant.

7. The OLED lighting device according to claim 6, wherein the protection layer is made of glass or plastic, and the sealant is made of an ultraviolet ray curable resin or a glass cement.

8. The OLED lighting device according to claim 1, wherein the substrate further includes a wiring, and the first electrode layer and the second electrode layer are electrically connected with the electrode terminal units by the wiring, respectively.

9. The OLED lighting device according to claim 8, wherein the first electrode layer is an anode electrode layer, the second electrode layer is a cathode electrode layer.
